(19) United States
(12) Patent Application Publication
(10) Pub. No.: US 2025/0056865 A1
(43) Pub. Date: Feb. 13, 2025

(54) SEMICONDUCTOR DEVICE BACKSIDE ISOLATION FEATURE INTEGRATION

(71) Applicant: International Business Machines Corporation, Armonk, NY (US)

(72) Inventors: Tao Li, Slingerlands, NY (US); Shay Reboh, Guilderland, NY (US); Julien Frougier, Albany, NY (US); Ruilong Xie, Niskayuna, NY (US)

(21) Appl. No.: 18/366,083

(22) Filed: Aug. 7, 2023

(51) Int. Cl. H01L 29/417; H01L 21/762; H01L 21/8234; H01L 27/088; H01L 29/06; H01L 29/423; H01L 29/775

(52) U.S. Cl. CPC H01L 29/41766; H01L 21/76224; H01L 21/823475; H01L 21/823481; H01L 27/088; H01L 29/0669; H01L 29/42392; H01L 29/775

(57) ABSTRACT

A semiconductor structure includes a front-end-of-line level formed by a plurality of field effect transistors. Each field effect transistor includes a source/drain region disposed on opposite sides of the field effect transistor. A metal contact region is disposed above and in contact with a first surface of two adjacent source/drain regions. Each of the two adjacent source/drain regions correspond to a field effect transistor. A backside isolation region cuts through the metal contact region from a backside of the plurality of field effect transistors for electrically isolating the two adjacent source/drain regions.

### BACKGROUND

The present invention generally relates to the field of semiconductor devices, and more particularly to power delivery to active devices.

Modern integrated circuits (IC) are made up of transistors, capacitors, and other devices that are formed on semiconductor substrates. On a substrate, these devices are initially isolated from one another but are later interconnected together to form functional circuits. Typical interconnect structures include lateral interconnections, such as metal lines (wirings), and vertical interconnects, such as vias and contacts. Power is provided to the integrated circuits through power rails, which are in the metal layers of integrated circuits. For example, the bottom metal layer (M₀ or M₁) may include a plurality of metal lines such as VDD power rails and VSS power rails.

As ICs continue to scale downward in size, backside power rails (BPRs), i.e., power rails that are formed in the backside of the wafer, usually under the transistor “fins”, and backside power delivery (“backside” is below the transistor substrate) have been proposed to alleviate design challenges and enable technology scaling beyond the 5 nm technology node. The BPR technology can free up resources for dense logic connections that limit modern processor performance, enable further scaling of a standard logic cell by removing the overhead in the area occupied by the power rails, and allow thicker low-resistance power rails that enable lower voltage (IR) drops. As ICs size is scaled downward and device density is increased, device middle-of-line (MOL) contact tip-to-tip patterning presents a challenging task during semiconductor device manufacturing. Therefore, there is a need for improved designs and techniques for backside contact cut patterning that provides better MOL tip-to-tip scaling.

### SUMMARY

According to an embodiment of the present disclosure, a semiconductor structure includes a front-end-of-line level including a plurality of field effect transistors, each field effect transistor including a source/drain region disposed on opposite sides of the field effect transistor, a metal contact region disposed above and in contact with a first surface of two adjacent source/drain regions, each of the two adjacent source/drain regions corresponding to a field effect transistor, and a backside isolation region cutting through the metal contact region from a backside of the plurality of field effect transistors, the backside isolation region electrically isolating the two adjacent source/drain regions.

In an embodiment, the semiconductor structure further includes an interlevel dielectric layer deposited above the field effect transistors, and a backside interlevel dielectric dispose below the field effect transistors, the backside interlevel dielectric being in contact with a second surface of the two adjacent source/drain regions, the second surface of the two adjacent source/drain regions opposing the first surface of the two adjacent source/drain regions.

In an embodiment, the semiconductor structure further includes dielectric spacers disposed on opposite sides of the backside interlevel dielectric.

In an embodiment, the backside isolation region includes a reverse tapered profile including a top portion of the backside isolation region embedded within the metal contact region having a first critical dimension, the top portion of the backside isolation region partially extending into the interlevel dielectric layer and occupying, at least in part, an area between adjacent conductive vias, and a bottom portion of the backside isolation region located between the dielectric spacers having a second critical dimension, wherein the second critical dimension is larger than the first critical dimension.

According to another embodiment of the present disclosure a method of forming a semiconductor structure includes forming a front-end-of-line level including a plurality of field effect transistors, each field effect transistor including a source/drain region disposed on opposite sides of the field effect transistor, forming a metal contact region disposed above, and in contact with, a first surface of two adjacent source/drain regions, each of the two adjacent source/drain regions corresponding to a field effect transistor, and forming a backside isolation region cutting through the metal contact region from a backside of the plurality of field effect transistors, the backside isolation region electrically isolating the two adjacent source/drain regions.

In an embodiment, the method further includes forming an interlevel dielectric layer above the field effect transistors, and forming a backside interlevel dielectric below the field effect transistors, the backside interlevel dielectric being in contact with a second surface of the two adjacent source/drain regions, the second surface of the two adjacent source/drain regions opposing the first surface of the two adjacent source/drain regions.

In an embodiment, the method further includes forming dielectric spacers on opposite sides of the backside interlevel dielectric.

In an embodiment, the backside isolation region includes a reverse tapered profile including a top portion of the backside isolation region embedded within the metal contact region having a first critical dimension, the top portion of the backside isolation region partially extending into the interlevel dielectric layer and occupying, at least in part, an area between adjacent conductive vias, and a bottom portion of the backside isolation region located between the dielectric spacers having a second critical dimension, wherein the second critical dimension is larger than the first critical dimension.

### BRIEF DESCRIPTION OF THE DRAWINGS

The following detailed description, given by way of example and not intended to limit the invention solely thereto, will best be appreciated in conjunction with the accompanying drawings, in which:

FIG. 1A is a top-down view of a semiconductor structure at an intermediate step during a semiconductor manufacturing process depicting different cross-sectional views used to describe embodiments of the present disclosure;

FIG. 1B is a cross-sectional view of the semiconductor structure taken along line X-X′, as depicted in FIG. 1A, after completing a front-end-of-line level, according to an embodiment of the present disclosure;

FIG. 1C is a cross-sectional view of the semiconductor structure taken along line Y-Y′, as depicted in FIG. 1A, according to an embodiment of the present disclosure;

FIG. 2A is a cross-sectional view of the semiconductor structure taken along line X-X, as depicted in FIG. 1A, after completing a middle-of-line level, according to an embodiment of the present disclosure;

FIG. 2B is a cross-sectional view of the semiconductor structure taken along line Y-Y, as depicted in FIG. 1A, according to an embodiment of the present disclosure;

FIG. 2C is a top-down view of the semiconductor structure, according to an embodiment of the present disclosure;

FIG. 3A is a cross-sectional view of the semiconductor structure taken along line X-X, as depicted in FIG. 1A, after forming lower interconnect structures, according to an embodiment of the present disclosure;

FIG. 3B is a cross-sectional view of the semiconductor structure taken along line Y-Y, as depicted in FIG. 1A, according to an embodiment of the present disclosure;

FIG. 4A is a cross-sectional view of the semiconductor structure taken along line X-X, as depicted in FIG. 1A, after completing a back-end-of-line level and conducting carrier wafer bonding, according to an embodiment of the present disclosure;

FIG. 4B is a cross-sectional view of the semiconductor structure taken along line Y-Y, as depicted in FIG. 1A, according to an embodiment of the present disclosure;

FIG. 5A is a cross-sectional view of the semiconductor structure taken along line X-X, as depicted in FIG. 1A, after wafer flip and substrate removal, according to an embodiment of the present disclosure;

FIG. 5B is a cross-sectional view of the semiconductor structure taken along line Y-Y, as depicted in FIG. 1A, according to an embodiment of the present disclosure;

FIG. 6A is a cross-sectional view of the semiconductor structure taken along line X-X, as depicted in FIG. 1A, after removing a first sacrificial layer and recessing silicon-containing areas, according to an embodiment of the present disclosure;

FIG. 6B is a cross-sectional view of the semiconductor structure taken along line Y-Y, as depicted in FIG. 1A, according to an embodiment of the present disclosure;

FIG. 7A is a cross-sectional view of the semiconductor structure taken along line X-X, as depicted in FIG. 1A, after depositing a backside interlayer dielectric and conducting a planarization process, according to an embodiment of the present disclosure;

FIG. 7B is a cross-sectional view of the semiconductor structure taken along line Y-Y, as depicted in FIG. 1A, according to an embodiment of the present disclosure;

FIG. 8A is a cross-sectional view of the semiconductor structure taken along line X-X, as depicted in FIG. 1A, after selectively etching shallow trench isolation regions, according to an embodiment of the present disclosure;

FIG. 8B is a cross-sectional view of the semiconductor structure taken along line Y-Y, as depicted in FIG. 1A, according to an embodiment of the present disclosure;

FIG. 9A is a cross-sectional view of the semiconductor structure taken along line X-X, as depicted in FIG. 1A, after forming dielectric spacers, according to an embodiment of the present disclosure;

FIG. 9B is a cross-sectional view of the semiconductor structure taken along line Y-Y, as depicted in FIG. 1A, according to an embodiment of the present disclosure;

FIG. 10A is a cross-sectional view of the semiconductor structure taken along line X-X, as depicted in FIG. 1A, after conducting a backside contact cut, according to an embodiment of the present disclosure;

FIG. 10B is a cross-sectional view of the semiconductor structure taken along line Y-Y, as depicted in FIG. 1A, according to an embodiment of the present disclosure;

FIG. 11A is a cross-sectional view of the semiconductor structure taken along line X-X, as depicted in FIG. 1A, after dielectric filling of the backside contact cut or backside isolation region, according to an embodiment of the present disclosure;

FIG. 11B is a cross-sectional view of the semiconductor structure taken along line Y-Y, as depicted in FIG. 1A, according to an embodiment of the present disclosure;

FIG. 12A is a cross-sectional view of the semiconductor structure taken along line X-X, as depicted in FIG. 1A, after backside contact patterning, according to an embodiment of the present disclosure;

FIG. 12B is a cross-sectional view of the semiconductor structure taken along line Y-Y, as depicted in FIG. 1A, according to an embodiment of the present disclosure;

FIG. 13A is a cross-sectional view of the semiconductor structure taken along line X-X, as depicted in FIG. 1A, after backside contact metallization and backside interconnect formation, according to an embodiment of the present disclosure; and

FIG. 13B is a cross-sectional view of the semiconductor structure taken along line Y-Y, as depicted in FIG. 1A, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

It is understood that although the disclosed embodiments include a detailed description of an exemplary nanosheet FET architecture having silicon and silicon germanium nanosheets, implementation of the teachings recited herein are not limited to the particular FET architecture described herein. Rather, embodiments of the present invention are capable of being implemented in conjunction with any other type of FET device now known or later developed.

As ICs size is scaled downward and the device density is increased, there may be a trade-off between the smallest dimension of a feature patterned in a semiconductor stack (the critical dimension) and the spacing between such features that may negatively impact device performance and reliability. Specifically, maintaining an appropriate tip-to-tip space between metal contacts can be a challenging task when the cell height is scaled. Backside power delivery network (BSPDN) offers a new opportunity for backside contact cut patterning that provides better MOL tip-to-tip scaling.

Embodiments of the present disclosure provide a semiconductor structure, and a method of making the same, in which wafer backside patterning techniques are used to improve backside contact cut patterning for better MOL contact tip-to-tip scaling. In the proposed embodiments, integration of backside transistor processes and backside power delivery network (BPDN) improves device scaling. The backside transistors and backside interconnects are formed by backside processes which are performed after completing BEOL processes and flipping the wafer over. Accordingly, the present embodiments address scalability issues by performing a trench contact cut process from the backside of the IC structure.

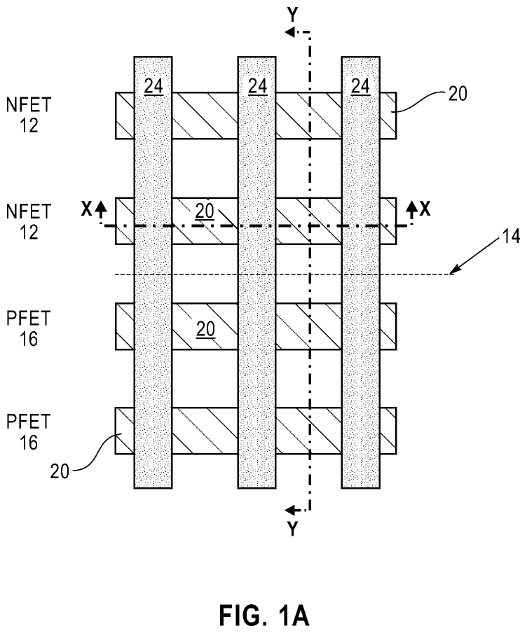

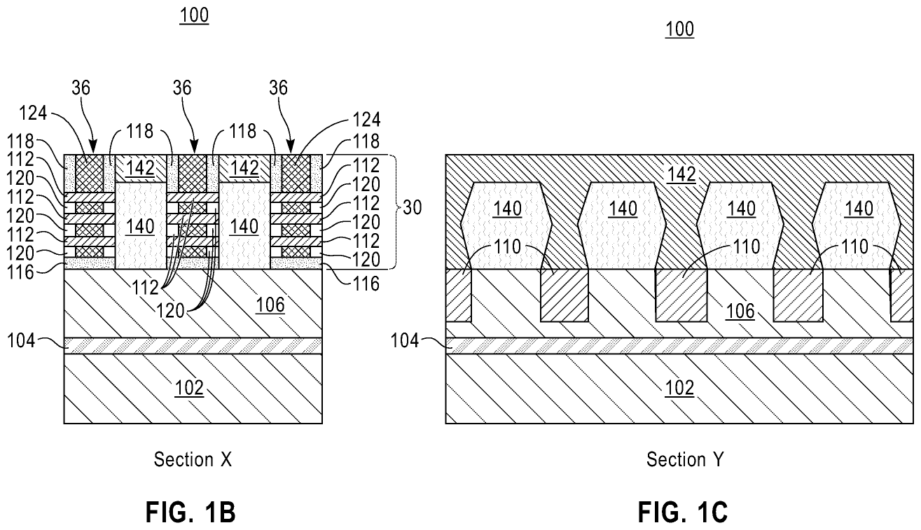

Embodiments by which the backside contact cut process can be performed to improve contact tip-to-tip scaling are described in detailed below by referring to the accompanying drawings in FIGS. 1-13B.

Referring now to FIG. 1A, a top-down view of a semiconductor structure 100 is shown at an intermediate step during a semiconductor manufacturing process, according to an embodiment of the present disclosure. Particularly, FIG. 1A depicts different cross-sectional views of the semiconductor structure 100 that will be used to describe embodiments of the present disclosure. The cross-sectional views are taken along line X-X and line Y-Y. As depicted in the figure, line X-X represents a cut along a nanosheet fin structure or nanosheet fin region 20 of the semiconductor structure 100, while line Y-Y represents a cut across one or more nanosheet fin structures 20 of the semiconductor structure 100.

In this embodiment, the cross-sectional view taken along line Y-Y further includes a view of NFET regions 12, PFET regions 16 and an area (N-P boundary) 14 located between NFET and PFET regions 12, 16. In one or more embodiments, the cut (line Y-Y) across the one or more fin structures 20 is parallel to a gate region 24 of the semiconductor structure 100.

Referring now to FIGS. 1B-1C, cross-sectional views of the semiconductor structure 100 after completion of a front-end-of-line (FEOL) level 30 are shown, according to an embodiment of the present disclosure. In this embodiment, FIG. 1B is a cross-sectional view of the semiconductor structure 100 taken along line X-X′, as depicted in FIG. 1A; and FIG. 1C is a cross-sectional view of the semiconductor structure 100 taken along line Y-Y′, as depicted in FIG. 1A.

Known semiconductor fabrication operations have been used to form the semiconductor structure 100 as depicted in FIGS. 1B-1C. Thus, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In contemporary semiconductor device fabrication processes a large number of semiconductor devices, such as field effect transistors (FETs), are fabricated on a single wafer. Some non-planar device architectures, including nanosheet FETs, provide increased device density and increased performance over planar devices. In nanosheet FETs, in contrast to conventional FETs, the gate stack wraps around the full perimeter of each nanosheet, enabling fuller depletion in the channel region, and reducing short-channel effects. The wrap-around gate structures used in nanosheet devices also enable greater management of leakage current in the active regions, even as drive currents increase.

Nanosheet FETs often include thin alternating layers (nanosheets) of different semiconductor materials arranged in a stack. Typically, nanosheets are patterned into nanosheet fins. Once the nanosheet fins are patterned, a gate stack is formed over a channel region of the nanosheet fins, and source/drain regions are formed adjacent to the gate stack. In some devices, once the gate stack or the source/drain regions have been formed, an etching process is performed to selectively remove nanosheet layers of one of the dissimilar materials from the fins. The etching process results in the undercutting and suspension of the layers of the nanosheet fin to form nanosheets or nanowires. The nanosheets or nanowires can be used to form gate-all-around devices.

Accordingly, in the depicted embodiment, FEOL semiconductor processing and structures have been completed in the semiconductor structure 100. As known by those skilled in the art, FEOL (e.g., FEOL level 30) is the first portion of IC fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

According to an embodiment, the semiconductor structure 100 depicted in FIGS. 1B-1C may include a substrate 102, a first sacrificial layer 104 located above the substrate 102, and a first semiconductor layer 106 disposed above the first sacrificial layer 104. In one or more embodiments, the first sacrificial layer 104 and the first semiconductor layer 106 are vertically stacked one on top of another in a direction perpendicular to the substrate 102, as illustrated in the figure.

The substrate 102 may be, for example, a bulk substrate, which may be made from any of several known semiconductor materials such as, for example, silicon, germanium, silicon-germanium alloy, and compound (e.g., III-V and II-VI) semiconductor materials. Non-limiting examples of compound semiconductor materials include gallium arsenide, indium arsenide, and indium phosphide, or indium gallium phosphide. Typically, the substrate 102 may be approximately, but is not limited to, several hundred microns thick. In other embodiments, the substrate 102 may be a layered semiconductor such as a silicon-on-insulator or SiGe-on-insulator, where a buried insulator layer, separates a base substrate from a top semiconductor layer.

The first sacrificial layer 104 can be formed on the substrate 102 using an epitaxial growth process. For instance, in the described embodiment, the first sacrificial layer 104 is formed by epitaxially growing a layer of SiGe with a germanium concentration varying from approximately 15 atomic percent to approximately 35 atomic percent. In some embodiments, the first sacrificial layer 104 can be made of epitaxially grown SiGe with a germanium concentration of approximately 30 atomic percent. In one or more embodiments, the first sacrificial layer 104 may act as an etch stop layer during subsequent substrate removal. Similarly, the first semiconductor layer 106 is formed by epitaxially growing a Si layer to a thickness varying from approximately 30 nm to approximately 250 nm, although other thicknesses are within the contemplated scope of the invention. In some embodiments, the first sacrificial layer 104 may include SiO₂. In such embodiments, the combined structure formed by the substrate 102, the first sacrificial layer 104, and the first semiconductor layer 106 can be an SOI wafer, with the first sacrificial layer 104 being the buried oxide (BOX) including a thickness ranging from approximately 20 nm to approximately 100 nm, and ranges therebetween.

In general, the first sacrificial layer 104 and the first semiconductor layer 106 can be formed by epitaxial growth by using the substrate 102 as the seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same or substantially similar crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Non-limiting examples of various epitaxial growth processes include rapid thermal chemical vapor deposition (RTCVD), low-energy plasma deposition (LEPD), ultra-high vacuum chemical vapor deposition (UHVCVD), atmospheric pressure chemical vapor deposition (APCVD), metalorganic chemical vapor deposition (MOCVD), low-pressure chemical vapor deposition (LPCVD), limited reaction processing CVD (LRPCVD), and molecular beam epitaxy (MBE). The temperature for an epitaxial deposition process can range from 500° C. to 900° C. Although higher temperatures typically results in faster deposition, the faster deposition may result in crystal defects and film cracking.

A number of different precursors may be used for the epitaxial growth of the first sacrificial layer 104 and the first semiconductor layer 106. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, helium and argon can be used.

The semiconductor structure 100 further includes a plurality of field effect transistors (FETs) or nanostructure devices 36 formed above the first semiconductor layer 106. According to an embodiment, the nanostructure devices 36 may include gate-all-around (GAA) devices. In some embodiments, the nanostructure devices 36 may include at least one of an NFET device or a PFET device. In some embodiments, the nanostructure devices 36 may include only NFET devices. In yet other embodiments, the nanostructure devices 36 may include only PFET devices.

Each of the nanostructure devices 36 include semiconductor channel layers 112. In the nanostructure devices 36 shown in FIG. 1B, the semiconductor channel layers 112 are laterally abutted by source/drain regions 140 and surrounded by a gate structure 124. The gate structure 124 controls flow of electrical current through the semiconductor channel layers 112 based on voltages applied at the gate structure 124 and at the source/drain regions 140.

In the depicted embodiment, the semiconductor channel layers 112 are formed by epitaxially growing a Si layer to a thickness varying from approximately 6 nm to approximately 12 nm, although other thicknesses are within the contemplated scope of the invention. In other embodiments, the semiconductor channel layers 112 may include silicon germanium, silicon carbide, silicon carbon phosphide or another suitable semiconductor material. In embodiments in which the nanostructure devices 36 are NFET devices, the source/drain regions 140 may include, for example, phosphorous-doped silicon (Si:P) or another suitable material. In embodiments in which the nanostructure devices 36 are PFET devices, the source/drain regions 140 may include, for example, silicon-germanium (SiGe) or another suitable material.

The gate structure 124 (i.e., replacement gate) is deposited above and between the semiconductor channel layers 112. The gate structure 124 includes gate dielectrics, such as hafnium oxide (HfO₂), zirconium dioxide (ZrO₂), hafnium-aluminum oxide (HfAlOx), hafnium-lanthanum oxide g (HfLaOx), etc., and one or more work function metals including, but not limited to, titanium nitride (TiN), tantalum nitride (TaN), titanium carbide (TiC), titanium aluminum carbide (TiAlC), and conducting metals including, for example, aluminum (Al), tungsten (W) or cobalt (Co). The gate structure 124 surrounds the semiconductor channel layers 112. In some embodiments, a gate cap (not shown) may be formed above the gate structure 124.

The nanostructure devices 36 also include gate spacers 118 deposited on sidewalls of the gate structure 124 and inner spacers 120 deposited between the semiconductor channel layers 112. The gate spacers 118 and the inner spacers 120 may include a dielectric material including, for example, a low-k material such as SiOCN, SiON, SiN, or SiOC.

In one or more embodiments, the spacer material deposited between a bottom surface of a nanostructure device 36 and the first semiconductor layer 106 can be referred to as a self-aligned substrate isolation (SASI) 116. In some embodiments, the self-aligned substrate isolation 116 and the gate spacers 118 may be composed of different materials.

It should be noted that, in one or more embodiments, a gate cut process can be conducted on the semiconductor structure 100 for isolating gate structures 124 corresponding to different CMOS cells. During the process, a gate cut region (not shown) can be formed either before replacement metal gate (RMG) or after RMG, and then filled with dielectrics such as SiO₂, SiN, SiBCN, SiOCN, SiOC, SiC, and the like.

In one or more embodiment, the semiconductor structure 100 further includes shallow trench isolation (STI) regions 110. The method of forming the STI regions 110 is standard and well-known in the art, it typically involves depositing an insulating material to substantially fill a plurality of trenches (not shown) created after processing steps in which portions of the first semiconductor layer 106 located between adjacent nanostructure devices 36 are removed from the semiconductor structure 100. According to an embodiment, the STI regions 110 electrically isolate the nanostructure devices 36 from one another. The STI regions 110 may be formed by, for example, CVD of dielectric materials. Non-limiting examples of dielectric materials to form the STI regions 110 include silicon oxide, silicon nitride, hydrogenated silicon carbon oxide, silicon based low-k dielectrics, flowable oxides, porous dielectrics, or organic dielectrics including porous organic dielectrics.

The semiconductor structure 100 further includes an interlevel dielectric layer 142 deposited above nanostructure device 36. The interlevel dielectric layer 142 covers an uppermost surface of the source/drain regions 140 located between adjacent nanostructure devices 36. The interlevel dielectric layer 142 fills voids and electrically isolates active regions within the FEOL level 30 of the semiconductor structure 100. The interlevel dielectric layer 142 may be formed by conformal deposition (e.g., CVD) of a dielectric material. Non-limiting examples of dielectric materials to form the interlevel dielectric layer 142 may include silicon oxide, silicon nitride, hydrogenated silicon carbon oxide, silicon based low-k dielectrics, flowable oxides, porous dielectrics, or organic dielectrics including porous organic dielectrics.

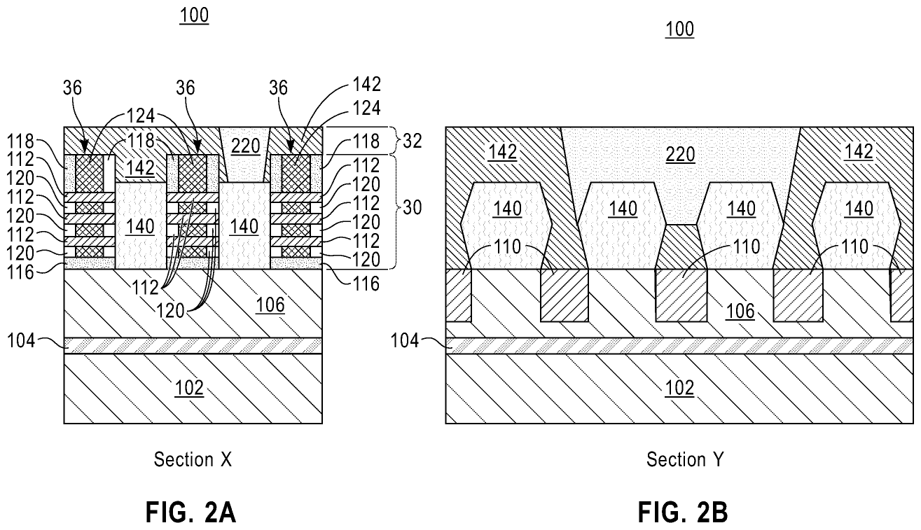

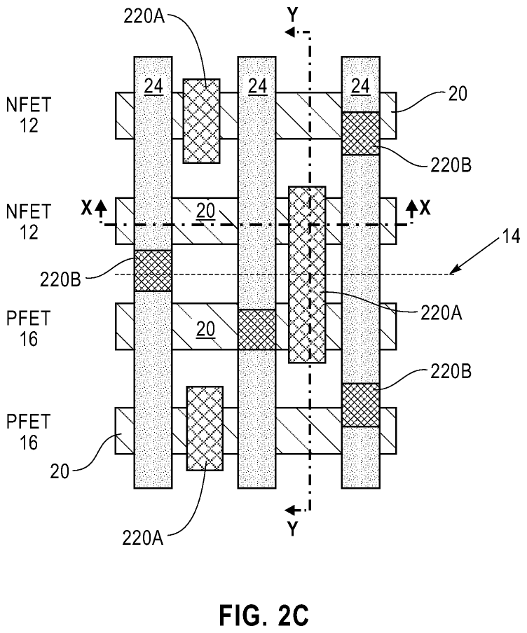

Referring now to FIGS. 2A-2C, cross-sectional views of the semiconductor structure 100 are shown after completion of a middle-of-line (MOL) level 32. In this embodiment, FIG. 2A is a cross-sectional view of the semiconductor structure 100 taken along line X-X as depicted in FIG. 1A, FIG. 2B is a cross-sectional view of the semiconductor structure 100 taken along line Y-Y as depicted in FIG. 1, and FIG. 2C is a top-down view of the semiconductor structure 100.

According to an embodiment, metal contacts 220 are formed in the semiconductor structure 100 for electrically connecting FEOL devices (i.e., nanostructure devices 36) to subsequently formed metal levels. The process of forming the metal contacts 220 is standard and well-known in the art. Typically, the process includes forming trenches (not shown) within the interlevel dielectric layer 142 and subsequently filling the trenches with a conductive material or a combination of conductive materials to form the metal contacts 220. As may be known by those skilled in the art, a second interlevel dielectric substantially similar to the (first) interlevel dielectric layer 142 is deposited above top surfaces of the nanostructures devices 36 prior to forming the metal contacts 220. For ease of illustration, without intent of limitation, the second interlevel dielectric will continue to be referred to as interlevel dielectric layer 142.

In one or more embodiments, the conductive material filling the metal contacts 220 may include a silicide liner (e.g., titanium (Ti), nickel (Ni), nickel-platinum (NiPt) alloy, etc.), a metal adhesion liner (e.g., titanium nitride (TiN)), and a conductive metal (e.g., aluminum (Al), tungsten (W), copper (Co), ruthenium (Ru), or any combination thereof).

The conductive material may be deposited by a suitable deposition process, for example, CVD, PECVD, PVD, plating, thermal or e-beam evaporation, or sputtering. A planarization process, for example, CMP, is performed to remove any conductive material from upper surfaces of the semiconductor structure 100. According to an embodiment, metal contacts 220 include source/drain contacts 220A that extend until an uppermost surface of the source/drain regions 140 and gate contacts 220B to the gate structure 124, as depicted in the top-down view of FIG. 2C. It should be noted that at least one metal contact 220 is in contact with two adjacent source/drain regions 140, as depicted in FIGS. 2B-2C.

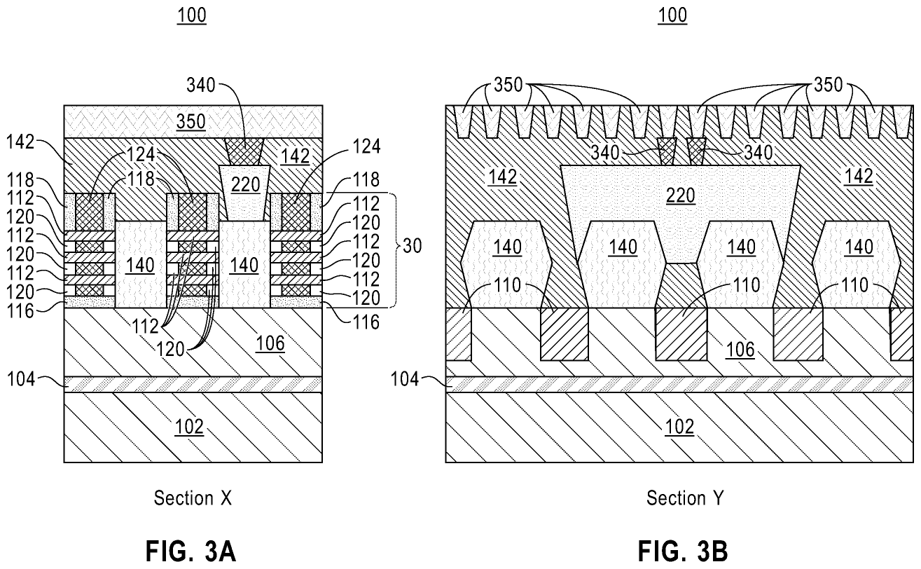

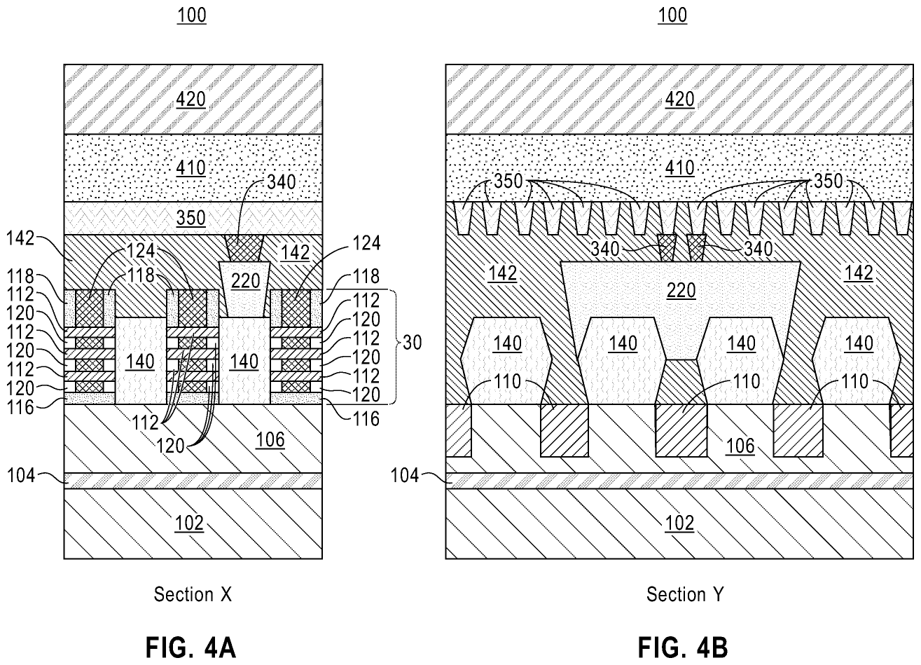

Referring now to FIGS. 3A-3B and FIGS. 4A-4B simultaneously, cross-sectional views of the semiconductor structure 100 are shown after forming lower interconnect structures, completing a back-end-of-line (BEOL) level 410, and conducting carrier wafer bonding. In this embodiment, FIGS. 3A and 4A are cross-sectional views of the semiconductor structure 100 taken along line X-X as depicted in FIG. 1, and FIGS. 3B and 4B are cross-sectional views of the semiconductor structure 100 taken along line Y-Y as depicted in FIG. 1.

According to an embodiment of the present disclosure, lower conductive structures (i.e., lines and/or vias) are formed in the semiconductor structure 100 for electrically connecting FEOL devices and the rest of the BEOL interconnect levels. Specifically, metal lines 350 are formed within the interlevel dielectric layer 142. The metal lines 350 are electrically connected on a first side to metal contacts 220 through conductive vias 340. First metal lines 350 are electrically connected on a second side, opposing the first side, to the rest of the BEOL interconnect level 410. Thus, metal lines 350 and conductive vias 340 allow electrically connecting the rest of the BEOL interconnect level 410 and FEOL device level 30.

In general, metal lines 350 (also referred to as wiring lines) provide electrical connections within the same metal level, and conductive vias 340 provide inter-level or vertical connections between different (metal) line levels. The metal lines 350 and conductive vias 340 are typically formed by etching a recess in the layer of dielectric material (i.e., interlevel dielectric layer 142) and filling the recess with a metal such as copper, tungsten, aluminum, etc., and corresponding barrier layers. The first metallization layer is often referred to as the M1 layer. Typically, a plurality of conductive vias 340 (i.e., V0 vias) are used to establish an electrical connection between the M1 layer and the underlying device level contacts (e.g., source/drain and gate contacts 220A, 220B in FIG. 2C).

With reference now to FIGS. 4A-4B, the semiconductor structure 100 further includes the BEOL interconnect level 410, which is formed above, and electrically connected to, the FEOL device level 30. Although not depicted in the figures, the BEOL interconnect level 410 typically includes contacts, insulating layers (dielectrics), metal levels, and bonding sites for chip-to-package connections, as may be known by those skilled in the art. As mentioned above, various steps in the manufacture of semiconductor devices and semiconductor-based ICs are well known and so, in the interest of brevity, many conventional steps will only be mentioned briefly herein or will be omitted entirely without providing the well-known process details.

According to an embodiment, after forming the BEOL interconnect level 410, the semiconductor structure 100 (i.e., the semiconductor wafer) is bonded to the carrier wafer (or auxiliary substrate) 420. The carrier wafer 420 may act as a reinforcing substrate for providing mechanical strength during processing (e g., thinning) of the semiconductor wafer. The process of bonding the semiconductor wafer to the carrier wafer 420 can be achieved by conventional wafer bonding process, such as dielectric-to-dielectric bonding or Cu-to-Cu bonding.

Accordingly, the carrier wafer 420 may include silicon oxide layers or SiCN layers, or any other layers applicable in the direct bonding technology applied in state-of-the-art packaging techniques. Bonding of the device wafer to the carrier wafer 420 takes place by such known direct bonding techniques, thus obtaining the assembly shown in FIGS. 4A-4B. Although not depicted in the figures, after bonding of the device wafer to the carrier wafer 420, the device wafer is flipped.

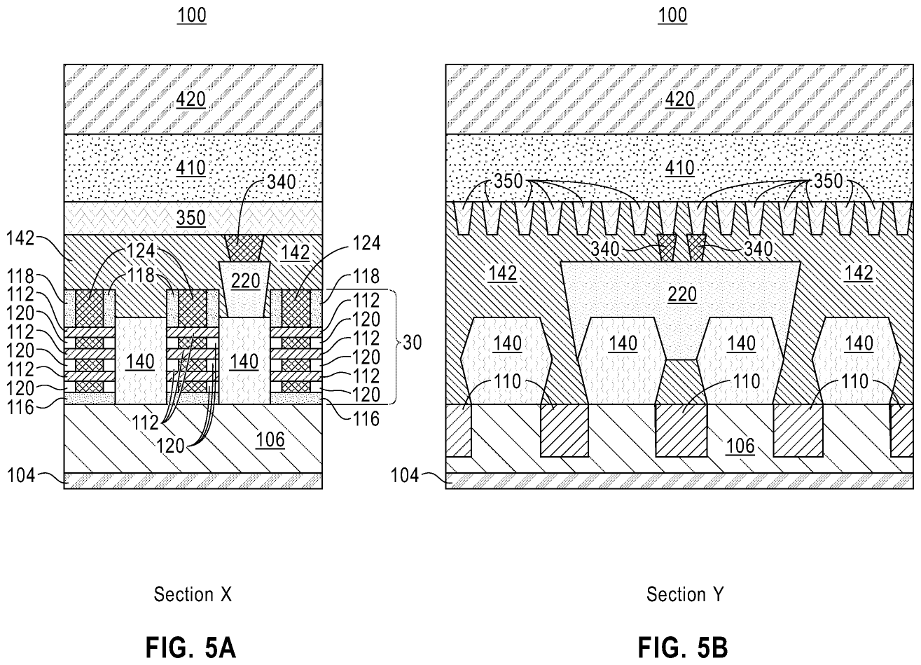

Referring now to FIGS. 5A-5B, cross-sectional views of the semiconductor structure 100 are shown after removing substrate 102 (FIGS. 4A-4B), according to an embodiment of the present disclosure. In this embodiment, FIG. 5A is a cross-sectional view of the semiconductor structure 100 taken along line X-X as depicted in FIG. 1A, and FIG. 5B is a cross-sectional view of the semiconductor structure 100 taken along line Y-Y as depicted in FIG. 1A.

In the depicted embodiment, after the wafer is flipped (not shown), the substrate 102 can be removed from the semiconductor structure 100 using regular grinding, CMP and selective etching processes including wet or dry etching techniques. In one or more embodiments, the grinding process is conducted until substantially removing the substrate 102 from the semiconductor structure 100 and only a few microns of Si remain. After that, an optional CMP process can be further used to reduce the thickness variation, and finally a highly selective Si etching process is used to remove the remaining substrate 102 from the semiconductor structure 100 selective to the first sacrificial layer 104. In the depicted embodiment, the first sacrificial layer 104 act as an etch stop during the highly selective Si removal process, preventing excessive Si etch which may damage the gate structures 124 and source/drain regions 140.

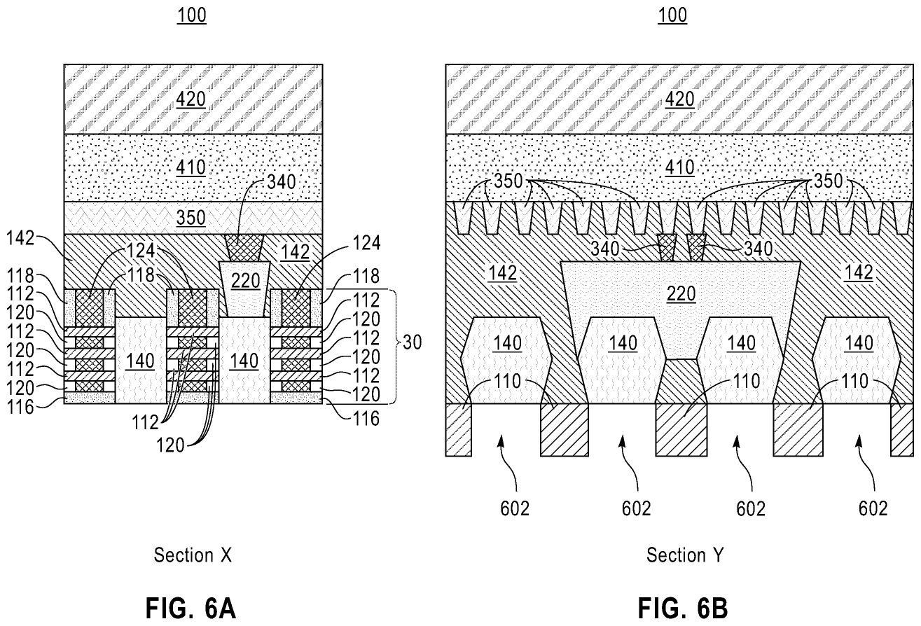

Referring now to FIGS. 6A-6B, cross-sectional views of the semiconductor structure 100 are shown after removing the first sacrificial layer 104 and recessing remaining Si-containing areas (i.e., the first semiconductor layer 106) depicted in FIGS. 5A-5B, according to an embodiment of the present disclosure. In this embodiment, FIG. 6A is a cross-sectional view of the semiconductor structure 100 taken along line X-X as depicted in FIG. 1A, and FIG. 6B is a cross-sectional view of the semiconductor structure 100 taken along line Y-Y as depicted in FIG. 1A.

Any suitable etching technique may be used to remove the first sacrificial layer 104 selective to the first semiconductor layer 106. In embodiments in which the first sacrificial layer 104 is made of SiGe a hot SC1 or dry HCl etch can be used to remove the first sacrificial layer 104. In embodiments in which the first sacrificial layer 104 is made of SiO₂, DHF wet clean can be used to remove the first sacrificial layer 104 from the semiconductor structure 100.

In one or more embodiments, following the removal of the first sacrificial layer 104, a highly selective Si etching process can be conducted to remove the first semiconductor layer 106 without damaging STI regions 110. As depicted in FIG. 6B, selectively recessing the first semiconductor layer 106 creates openings 602. Openings 602 expose a lowermost portion of the source/drain regions 140 opposing an uppermost portion of the source/drain regions 140 in contact with metal contacts 220 and interlevel dielectric 142, as can be observed in FIG. 6B. Similarly, a lowermost surface of the self-aligned substrate isolation 116 can also be exposed after removing the first semiconductor layer 106, as shown in FIG. 6A.

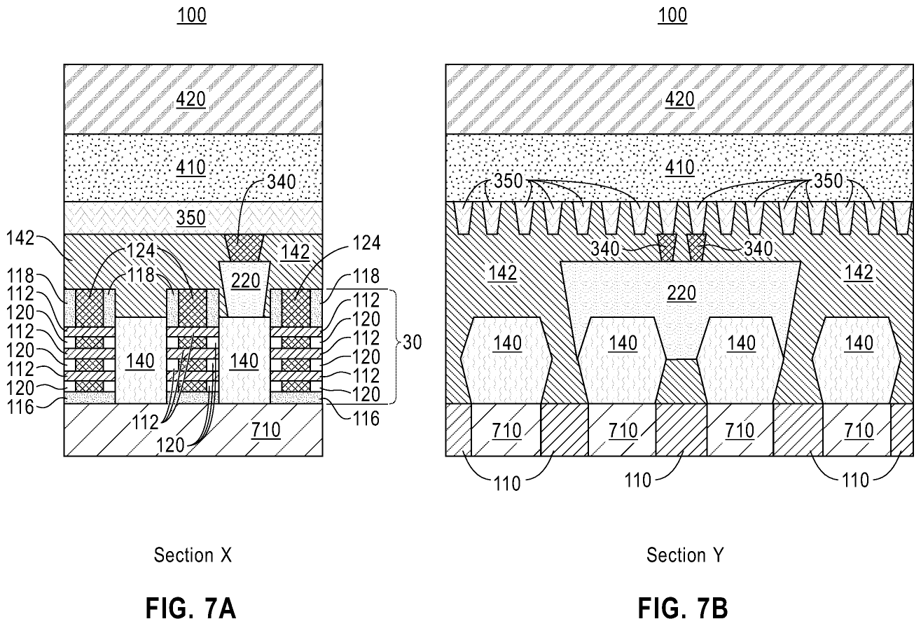

Referring now to FIGS. 7A-7B, cross-sectional views of the semiconductor structure 100 are shown after depositing a backside interlayer dielectric (BILD) 710 and conducting a planarization process, according to an embodiment of the present disclosure. In this embodiment, FIG. 7A is a cross-sectional view of the semiconductor structure 100 taken along line X-X as depicted in FIG. 1A, and FIG. 7B is a cross-sectional view of the semiconductor structure 100 taken along line Y-Y as depicted in FIG. 1A.

According to an embodiment, the BILD 710 can be formed using standard methods and materials, such as those used to form the interlevel dielectric layer 142 described above with reference to FIGS. 1B-1C. The BILD 710 substantially fills openings 602 (FIGS. 6A-6B); thus, the BILD 710 deposits above and in direct contact with exposed lowermost portions of the source/drain regions 140 and self-aligned substrate isolation 116. In an exemplary embodiment, a thickness of the BILD 710 may vary between approximately 40 nm to approximately 300 nm, and ranges therebetween. In one or more embodiments, a planarization process (e.g., CMP) can be conducted on the semiconductor structure 100 after forming the BILD 710. After conducting the planarization process, exposed surfaces of the STI regions 110 and BILD 710 are substantially coplanar.

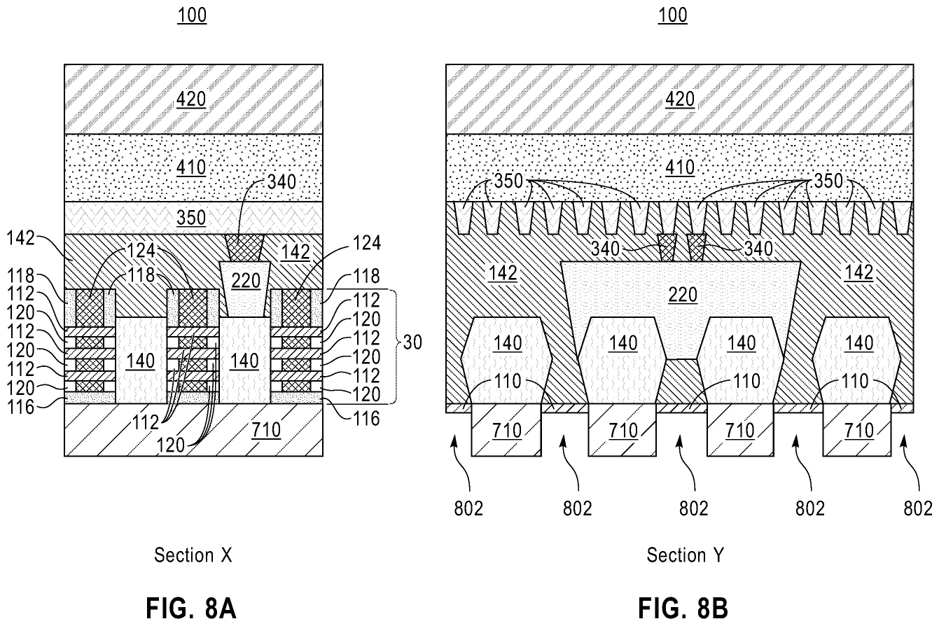

Referring now to FIGS. 8A-8B, cross-sectional views of the semiconductor structure 100 are shown after selectively etching the STI regions 110, according to an embodiment of the present disclosure. In this embodiment, FIG. 8A is a cross-sectional view of the semiconductor structure 100 taken along line X-X as depicted in FIG. 1A, and FIG. 8B is a cross-sectional view of the semiconductor structure 100 taken along line Y-Y as depicted in FIG. 1A.

In the depicted embodiment, any suitable etching technique can be used to recess the STI regions 110 selective to the BILD 710. In an exemplary embodiment, a selective reactive ion etch (RIE) process or a selective wet etch process can be used to recess the STI regions 110 selective to the BILD 710. In one or more embodiments, a portion of the STI regions 110, having a thickness varying between approximately 0 nm to approximately 30 nm, remains in the semiconductor structure 100, as depicted in FIG. 8B. Etching the STI regions 110 creates STI openings 802 in the semiconductor structure 100. It should be noted that, in some embodiments, the STI regions 110 can be completely removed from the semiconductor structure 100.

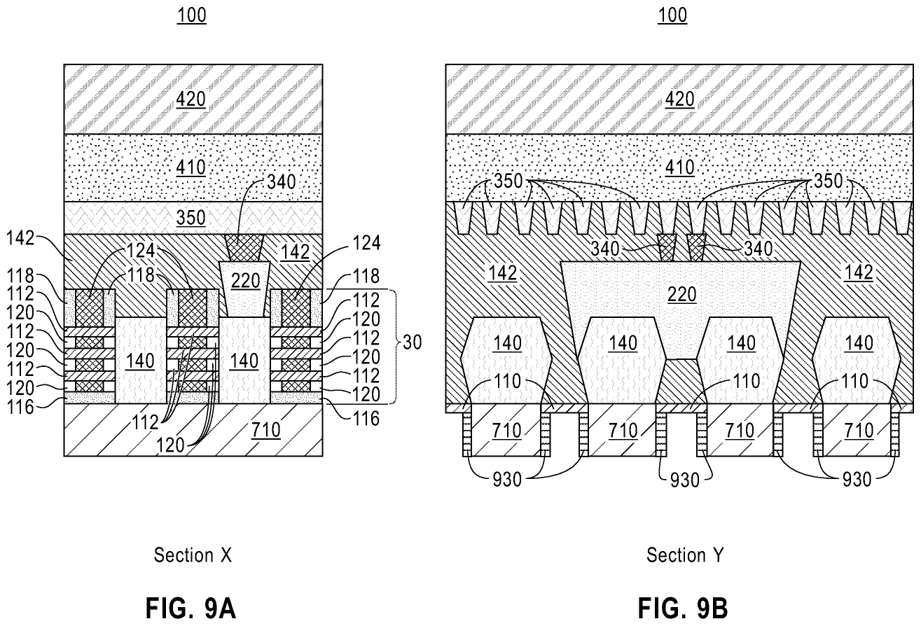

Referring now to FIGS. 9A-9B, cross-sectional views of the semiconductor structure 100 are shown after forming dielectric spacers 930, according to an embodiment of the present disclosure. In this embodiment, FIG. 9A is a cross-sectional view of the semiconductor structure 100 taken along line X-X as depicted in FIG. 1A, and FIG. 9B is a cross-sectional view of the semiconductor structure 100 taken along line Y-Y as depicted in FIG. 1A.

The dielectric spacers 930 are formed on opposing sidewalls of the BILD 710, as depicted in FIG. 9B. In embodiments in which the STI regions 110 are not completely removed, a first surface of the dielectric spacers 930 is in contact with the remaining portions of the STI regions 110, while a second surface of the dielectric spacers 930, opposing the second surface, is substantially coplanar with the BILD 710. According to an embodiment, forming the dielectric spacers 930 reduces a critical dimension (CD) of the STI openings 802 depicted in FIG. 8B. By doing this a critical dimension of subsequently formed contact isolation features can be controlled, as will be described in detail below. In one or more embodiments, the dielectric spacers 930 are formed using similar materials and deposition processes as those used to form gate spacers 118 described above with reference to FIGS. 1B-1C. In an exemplary embodiment, the dielectric spacers 930 may be made of silicon nitride (SiN).

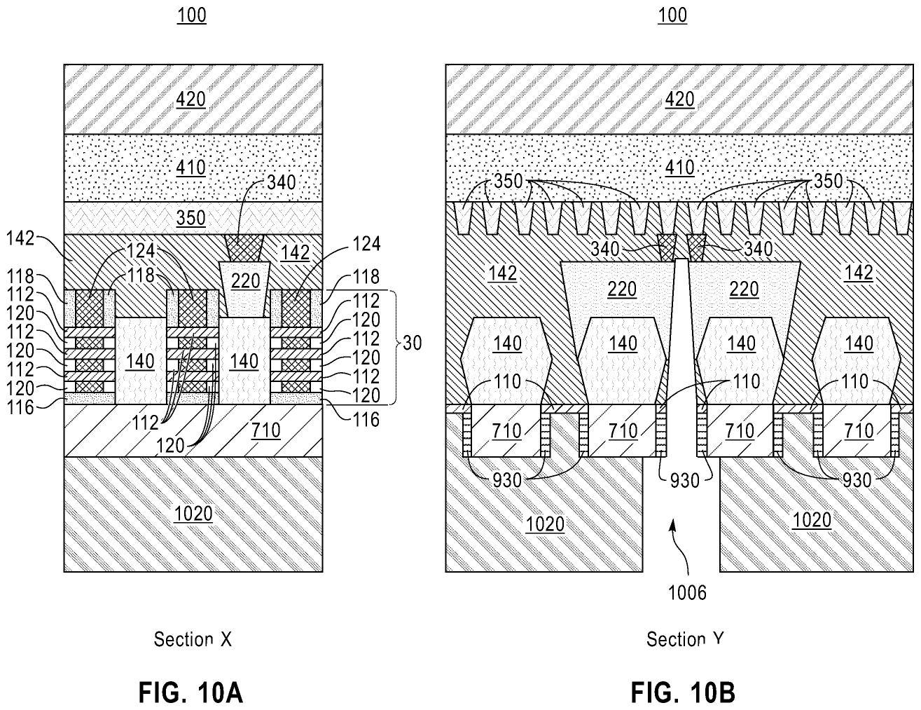

Referring now to FIGS. 10A-10B, cross-sectional views of the semiconductor structure 100 are shown after conducting a backside contact cut process, according to an embodiment of the present disclosure. In this embodiment, FIG. 10A is a cross-sectional view of the semiconductor structure 100 taken along line X-X as depicted in FIG. 1A, and FIG. 10B is a cross-sectional view of the semiconductor structure 100 taken along line Y-Y as depicted in FIG. 1A.

According to an embodiment, an organic planarization layer (OPL), or simply first planarization layer 1020 can be deposited on the semiconductor structure 100. The planarization layer 1020 can be made of any organic planarizing material that is capable of effectively preventing damage of underlying layers during subsequent etching processes. The planarization layer 1020 can include, but is not necessarily limited to, an organic polymer including C, H, and N. In an embodiment, the organic planarizing material can be free of silicon (Si). In another embodiment, the organic planarizing material can be free of Si and fluorine (F). As defined herein, a material is free of an atomic element when the level of the atomic element in the material is at or below a trace level detectable with analytic methods available in the art. Non-limiting examples of organic planarizing materials for forming the first planarization layer 1020 may include JSR HM8006, JSR HM8014, AZ UM10M2, Shin Etsu ODL 102, or other similar commercially available materials. The first planarization layer 1020 may be deposited by, for example, spin coating.

With continued reference to FIGS. 10A-10B, a lithography process followed by an etching process is conducted on the semiconductor structure 100 for etching the planarization layer 1020 to form a contact opening 1006, as shown in FIG. 10B. In some embodiments, etching the first planarization layer 1020 can be conducted by, for example, an OPL RIE including a trace point detection. The contact opening 1006 extends or cuts through at least one metal contact 220 located above, and in electrical contact with, two adjacent source/drain regions 140. The contact opening 1006 creates a gap that divides the at least one metal contact 220 into two regions, with each region of the divided at least one metal contact 220 being in contact with a source/drain region 140.

After forming the contact openings 1006, any suitable etching process can be used to remove the first planarization layer 1020 from the semiconductor structure 100. It should be noted that, although not depicted in the figures, after removing the first planarization layer 1020 a plurality of openings remain within dielectric spacers 930, which may subsequently be filled with a dielectric material, as will be described in detail below.

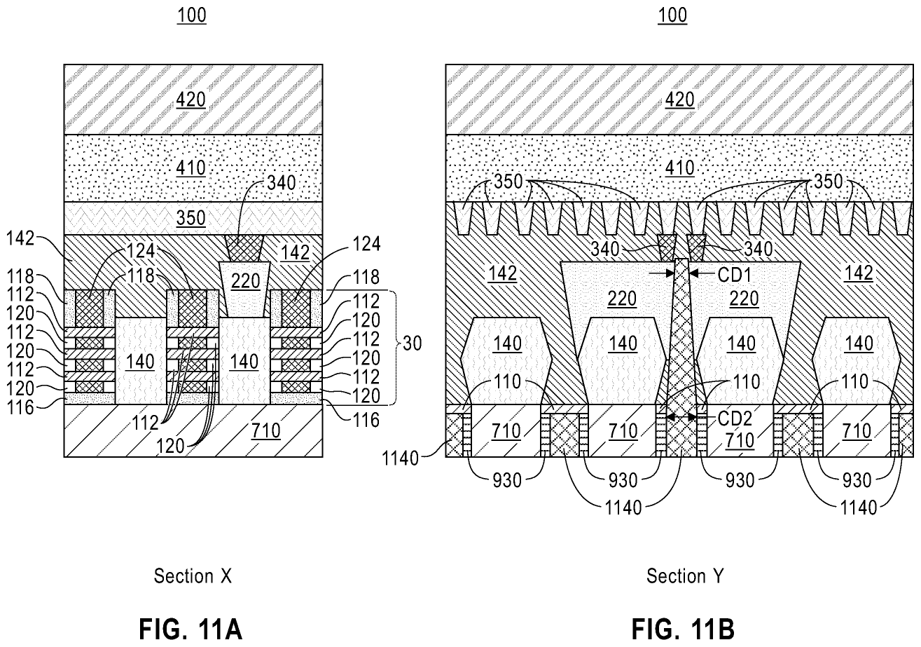

Referring now to FIGS. 11A-11B, cross-sectional views of the semiconductor structure 100 are shown after forming a backside contact cut or backside isolation region 1140, according to an embodiment of the present disclosure. In this embodiment, FIG. 11A is a cross-sectional view of the semiconductor structure 100 taken along line X-X as depicted in FIG. 1A, and FIG. 11B is a cross-sectional view of the semiconductor structure 100 taken along line Y-Y as depicted in FIG. 1A.

In this embodiment, a dielectric material can be deposited within the contact opening 1006 (FIGS. 10A-10B) to form a backside isolation region 1140 between the at least one metal contact 220 previously merged above the two adjacent source/drain regions 140. Stated differently, the backside isolation region 1140 can be formed from a backside of the semiconductor structure 100 to electrically separate metal contacts 220 merging above neighboring source/drain regions 140. Thus, after forming the backside isolation region 1140, each portion of the metal contact 220 is in contact with a source/drain region 140 and each metal contact/source/drain region structure is electrically isolated from one another. As shown in FIG. 11B, the dielectric material forming the backside isolation region 1140 also deposits within openings or void areas located between adjacent dielectric spacers 930 (i.e., openings left in the semiconductor structure 100 after removing the first planarization layer 1020) to create additional backside isolation regions 1140 within the semiconductor structure 100. However, as depicted in the figures, these additional backside isolation regions 1140 do not extend through any metal contact 220.

In an exemplary embodiment, the dielectric material used to form the backside isolation regions 1140 may include silicon nitride and may be deposited using a conformal deposition process (e.g., CVD). The dielectric material substantially fills the narrower portion of the contact opening 1006 (FIGS. 10A-10B) extending towards the interlevel dielectric layer 142.

As depicted in FIG. 11B, the backside isolation region 1140 separating the at least one metal contact 220 may include a top portion having a first critical dimension (CD1) and a bottom portion having a second critical dimension (CD2), with CD2 being larger than CD1 (CD2>CD1). Thus, the backside isolation region 1140 separating the at least one metal contact 220 may have tapering sidewalls formed at an angle narrowing towards the interlevel dielectric layer 142. The bottom portion of the backside isolation region 1140 having the larger critical dimension CD2 is abutted by the dielectric spacers 930.

In the depicted embodiment, the backside isolation region 1140 dividing the at least one metal contact 220 includes a frontside contact cut formed from a backside of the semiconductor structure 100. Such backside contact cut formation may allow accurate cut position and may enable tip-to-tip (T2T) spaces as small as 6 nm. It should be noted that the top portion of the backside isolation region 1140 having the first critical dimension (CD1) extends past the at least one metal contact 220 into the interlevel dielectric layer 142, partially occupying an area between adjacent conductive vias 340, as depicted in FIG. 11B. Accordingly, the T2T reduction enabled by the backside isolation region 1140 helps conductive vias 340 to be electrically separated from one another while remaining in electric contact with a respective side of the at least one metal contact 220 divided by the backside isolation region 1140. In one or more embodiments, a planarization process can be conducted on the semiconductor structure 100 after forming the isolation region 1140.

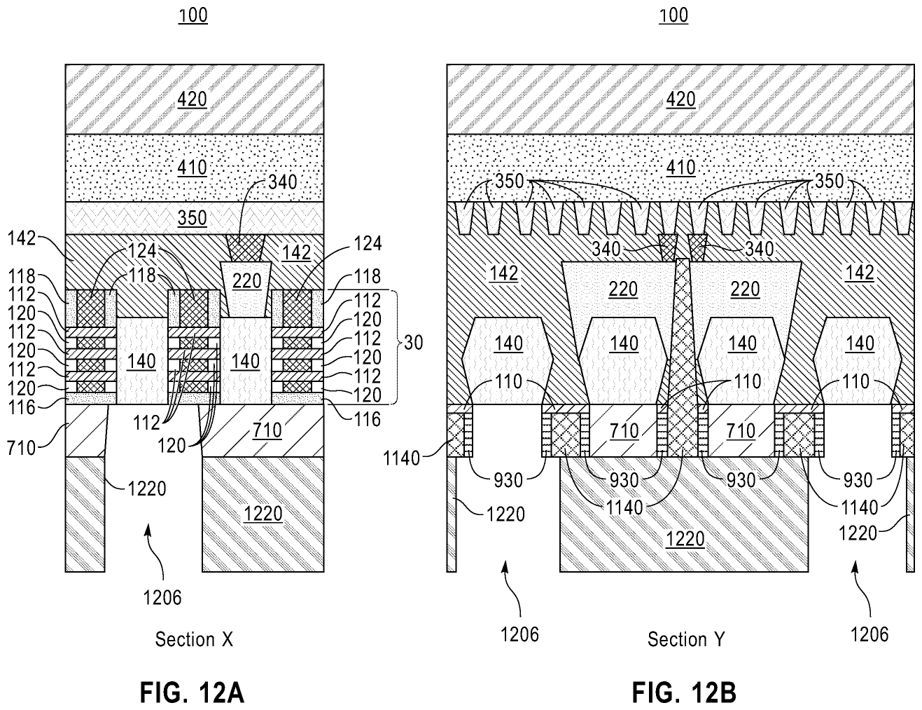

Referring now to FIGS. 12A-12B, cross-sectional views of the semiconductor structure 100 are shown after backside contact patterning, according to an embodiment of the present disclosure. In this embodiment, FIG. 12A is a cross-sectional view of the semiconductor structure 100 taken along line X-X as depicted in FIG. 1A, and FIG. 12B is a cross-sectional view of the semiconductor structure 100 taken along line Y-Y as depicted in FIG. 1A.

According to an embodiment, another organic planarization layer (OPL), or second planarization layer 1220 can be deposited on the semiconductor structure 100. The second planarization layer 1220 can be made of similar materials and be deposited using analogous techniques as those used to form the first planarization layer 1020, described above with reference to FIGS. 10A-10B.

A lithography process followed by an etching process is conducted on the semiconductor structure 100 for etching the second planarization layer 1220 to form second openings 1206. In some embodiments, etching the second planarization layer 1220 can be conducted by, for example, an OPL RIE including a trace point detection. After patterning the second planarization layer 1220, an etching process can be conducted on the semiconductor structure 100 to remove portions of the BILD 710 selective to the dielectric spacers 930 and source/drain regions 140. In an exemplary embodiment, a plasma etch process using HBr chemistry can be conducted on the semiconductor structure 100 to selectively remove the BILD 710. As shown in the figures, etching the BILD 710 increases a size of the second openings 1206 exposing portions of one or more source/drain regions 140. It should be noted that due to the selectivity between the BILD 710 and the dielectric spacers 930, the conducted etching process becomes a self-aligned etch that facilitates the formation of backside contacts.

In one or more embodiments, the second openings 1206 expose a first (bottom) surface or backside surface of one or more source/drain regions 140 that are not electrically connected to a metal contact 220. In one or more embodiments, a location of the second openings 1206 can be selected based on the desired location of subsequently formed backside metal contacts.

Thus, the second openings 1206 (i.e., backside contact vias) expose one or more of the source/drain regions 140, as depicted in FIGS. 12A-12B. More particularly, an area of the one or more source/drain regions 140 exposed by the second openings 1206 corresponds to a first (bottom) surface of a source/drain region 140 opposing a second (top) surface of the source/drain region 140 that is in contact with the interlevel dielectric layer 142.

As can be observed in the figures, the second openings 1206 expose the first surface of at least one source/drain region 140 that is adjacent to at least another source/drain region 140 in electric contact with a metal contact 220. It should be noted that the depicted location of second openings 1206 is for illustration purposes only, it may be understood that different locations can be selected based on design requirements.

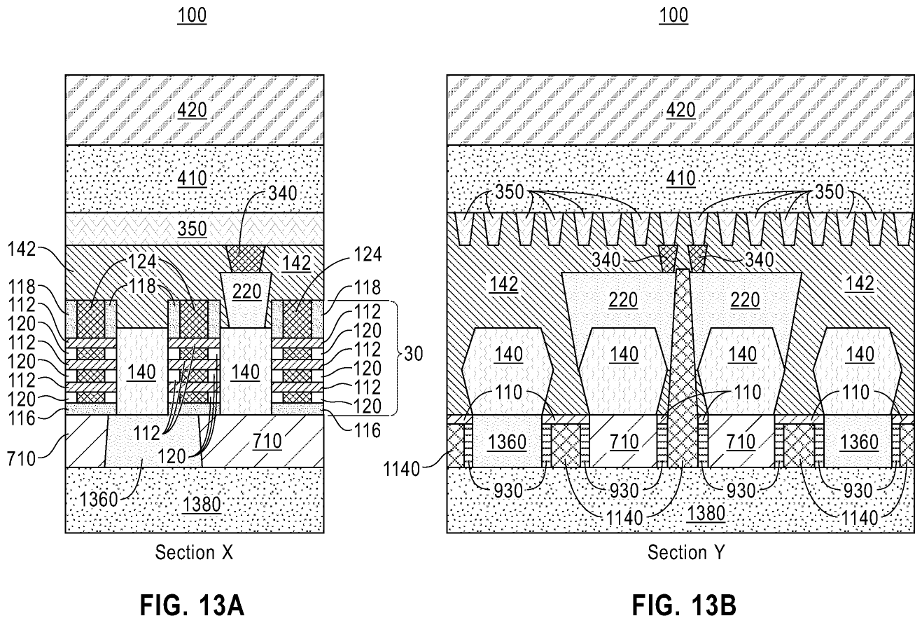

Referring now to FIGS. 13A-13B, cross-sectional views of the semiconductor structure 100 are shown after backside contact metallization and backside interconnect formation, according to an embodiment of the present disclosure. In this embodiment, FIG. 13A is a cross-sectional view of the semiconductor structure 100 taken along line X-X as depicted in FIG. 1A, and FIG. 13B is a cross-sectional view of the semiconductor structure 100 taken along line Y-Y as depicted in FIG. 1A.

In the depicted embodiment, a backside metal is deposited in the semiconductor structure 100 substantially filling the second openings 1206 (FIGS. 12A-12B) to form backside metal contacts 1360 to one or more source/drain regions 140. In one or more embodiments, backside metal contacts 1360 can be formed between neighboring source/drain regions 140 located within NFET regions or PFET regions of the semiconductor structure 100. In the depicted embodiment, backside metal contacts 1360 are formed in direct contact with the first (bottom) surface of the one or more source/drain regions 140. Backside metal contacts 1360 can be formed using similar materials and deposition techniques as those used to form the metal contacts 220.

A backside interconnect structure 1380 can be formed above and in contact with the backside metal contacts 1360. It should be noted that for ease of illustration, without intent of limitation, the backside interconnect structure 1380 is simplistically depicted as a single-layer region. However, those skilled in the art may understand that the simplistically depicted backside interconnect structure 1380 may be composed of a plurality of interconnect structures including, for example, backside power rails (BPRs) and backside power delivery network (BSPDN) made according to known techniques. Depending on the exact function of the transistor arrangement, a number of the source/drain regions 140 may be connected to backside power and ground via the backside metal contacts 1360.

It should be noted that the BEOL interconnect level 410 in the semiconductor structure 100 manufactured according to the disclosed technology is separated from the backside interconnect structure 1380, thereby increasing the routing resources in the semiconductor structure 100 for signal wirings in the BEOL interconnect level 410.

Accordingly, the previously described embodiments provide a self-aligned backside contact cut dielectric structure, i.e., backside isolation region 1140, formed between source/drain (epitaxial) regions 140 of two neighboring FETs or nanostructure devices 36. The self-aligned contact cut dielectric structure electrically isolates metal contacts 220 (i.e., MOL contacts) of the two neighboring FETs. The self-aligned backside contact cut dielectric structure includes a top region located near the metal contacts 220 having a first critical dimension (CD1) and a bottom region abutted by the dielectric spacers 930 having a second critical dimension (CD2), with CD2 being larger than CD1 (CD2>CD1). A backside of the source/drain regions 140 of the two neighboring FETs is connected to a self-aligned BILD 710. In one or more embodiments, a backside of the nanostructure devices 36 without a MOL metal contact 220 is in contact with a self-aligned backside contact (BSCA) 1360. Dielectric spacers 930 are disposed on each side of the backside contact 1360. The backside contact 1360 electrically connects FETs or nanostructure devices 36 to a backside interconnect structure 1380 including a backside power delivery network (BSPDN).

According to embodiments of the present disclosure a semiconductor structure having a self-aligned backside isolation region includes a front-end-of-line level including a plurality of field effect transistors. Each field effect transistor includes a source/drain region disposed on opposite sides of the field effect transistor. The semiconductor structure further includes a metal contact region disposed above a first surface of two adjacent source/drain regions, and a backside isolation region cutting through the metal contact region. The backside isolation region electrically isolates the two adjacent source/drain regions.

In one or more embodiments, the semiconductor structure further includes an interlevel dielectric layer deposited above the field effect transistors, and a backside interlevel dielectric dispose below the field effect transistors. The backside interlevel dielectric is in contact with a second surface of the two adjacent source/drain regions, with the second surface of the two adjacent source/drain regions opposing the first surface of the two adjacent source/drain regions.

In one or more embodiments, the semiconductor structure further includes dielectric spacers disposed on opposite sides of the backside interlevel dielectric.

In one or more embodiments, the backside isolation region includes a reverse tapered profile. The reverse tapered profile is formed by a top portion of the backside isolation region embedded within the metal contact region having a first critical dimension and a bottom portion of the backside isolation region located between the dielectric spacers having a second critical dimension, where the second critical dimension is larger than the first critical dimension. In one or more embodiments, the top portion of the backside isolation region partially extends into the interlevel dielectric layer and occupies, at least in part, an area between adjacent conductive vias.

In one or more embodiments, portions of the backside isolation region are located between the dielectric spacers with a bottom surface of the backside isolation region being flushed with a bottom surface of the dielectric spacers and a bottom surface of the backside interlevel dielectric.

In one or more embodiments, the semiconductor structure further includes a shallow trench isolation region located between a bottom portion of the interlevel dielectric and upper surfaces of the dielectric spacers and the backside isolation region

In one or more embodiments, the metal contact region electrically connects a first side of the two adjacent source/drain regions to a back-end-of-line level.

In one or more embodiments, the semiconductor structure further includes a backside metal contact within the backside interlevel dielectric layer. The backside metal contact electrically connects a second side of at least another source/drain region without a metal contact region to a backside interconnect, where a first side of the at least another source/drain region is in contact with the interlevel dielectric layer and the backside metal contact is abutted by the dielectric spacers.

In one or more embodiments, the semiconductor structure further includes a carrier wafer located above the back-end-of-line level.

In one or more embodiments, each of the field effect transistors further includes a gate structure located above and surrounding a plurality of channel layers.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a front-end-of-line level including a plurality of field effect transistors, each field effect transistor including a source/drain region disposed on opposite sides of the field effect transistor;
a metal contact region disposed above and in contact with a first surface of two adjacent source/drain regions, each of the two adjacent source/drain regions corresponding to a field effect transistor; and
a backside isolation region cutting through the metal contact region from a backside of the plurality of field effect transistors, the backside isolation region electrically isolating the two adjacent source/drain regions.

2. The semiconductor structure of claim 1, further comprising:
an interlevel dielectric layer deposited above the field effect transistors; and
a backside interlevel dielectric dispose below the field effect transistors, the backside interlevel dielectric being in contact with a second surface of the two adjacent source/drain regions, the second surface of the two adjacent source/drain regions opposing the first surface of the two adjacent source/drain regions.

3. The semiconductor structure of claim 2, further comprising:
dielectric spacers disposed on opposite sides of the backside interlevel dielectric.

4. The semiconductor structure of claim 1, wherein the backside isolation region comprises a reverse tapered profile.

5. The semiconductor structure of claim 4, wherein the backside isolation region having the reverse tapered profile comprises:
a top portion of the backside isolation region embedded within the metal contact region having a first critical dimension, the top portion of the backside isolation region partially extending into the interlevel dielectric layer and occupying, at least in part, an area between adjacent conductive vias; and
a bottom portion of the backside isolation region located between the dielectric spacers having a second critical dimension, wherein the second critical dimension is larger than the first critical dimension.

6. The semiconductor structure of claim 3, wherein portions of the backside isolation region are located between the dielectric spacers with a bottom surface of the backside isolation region being flushed with a bottom surface of the dielectric spacers and a bottom surface of the backside interlevel dielectric.

7. The semiconductor structure of claim 3, further comprising:
a shallow trench isolation region located between a bottom portion of the interlevel dielectric and upper surfaces of the dielectric spacers and the backside isolation region.

8. The semiconductor structure of claim 1, wherein the metal contact region electrically connects a first side of the two adjacent source/drain regions to a back-end-of-line level.

9. The semiconductor structure of claim 3, further comprising:
a backside metal contact within the backside interlevel dielectric layer, the backside metal contact electrically connecting a second side of at least another source/drain region without a metal contact region to a backside interconnect, wherein a first side of the at least another source/drain region is in contact with the interlevel dielectric layer and the backside metal contact is abutted by the dielectric spacers.

10. The semiconductor structure of claim 8, further comprising:
a carrier wafer located above the back-end-of-line level.

11. The semiconductor structure of claim 1, wherein each of the field effect transistors further comprises:
a gate structure located above and surrounding a plurality of channel layers.

12. A method of forming a semiconductor structure, comprising:
forming a front-end-of-line level including a plurality of field effect transistors, each field effect transistor including a source/drain region disposed on opposite sides of the field effect transistor;
forming a metal contact region disposed above, and in contact with, a first surface of two adjacent source/drain regions, each of the two adjacent source/drain regions corresponding to a field effect transistor; and
forming a backside isolation region cutting through the metal contact region from a backside of the plurality of field effect transistors, the backside isolation region electrically isolating the two adjacent source/drain regions.

13. The method of claim 12, further comprising:
forming an interlevel dielectric layer above the field effect transistors; and
forming a backside interlevel dielectric below the field effect transistors, the backside interlevel dielectric being in contact with a second surface of the two adjacent source/drain regions, the second surface of the two adjacent source/drain regions opposing the first surface of the two adjacent source/drain regions.

14. The method of claim 13, further comprising:
forming dielectric spacers on opposite sides of the backside interlevel dielectric.

15. The method of claim 12, wherein the backside isolation region comprises a reverse tapered profile.

16. The method of claim 14, wherein the backside isolation region having the reverse tapered profile comprises:
a top portion of the backside isolation region embedded within the metal contact region having a first critical dimension, the top portion of the backside isolation region partially extending into the interlevel dielectric layer and occupying, at least in part, an area between adjacent conductive vias; and
a bottom portion of the backside isolation region located between the dielectric spacers having a second critical dimension, wherein the second critical dimension is larger than the first critical dimension.

17. The method of claim 14, wherein portions of the backside isolation region are located between the dielectric spacers with a bottom surface of the backside isolation region being flushed with a bottom surface of the dielectric spacers and a bottom surface of the backside interlevel dielectric.

18. The method of claim 14, further comprising:
forming a shallow trench isolation region between a bottom portion of the interlevel dielectric and upper surfaces of the dielectric spacers and the backside isolation region.

19. The method of claim 12, wherein the metal contact region electrically connects a first side of the two adjacent source/drain regions to a back-end-of-line level.

20. The method of claim 19, further comprising:
forming a backside metal contact within the backside interlevel dielectric layer, the backside metal contact electrically connecting a second side of at least another source/drain region without a metal contact region to a backside interconnect, wherein a first side of the at least another source/drain region is in contact with the interlevel dielectric layer and the backside metal contact is abutted by the dielectric spacers;
forming a gate structure above and surrounding a plurality of channel layers; and
forming a carrier wafer above the back-end-of-line level.
